(19) United States
(12) Patent Application Publication
(10) Pub. No.: US 2019/0035918 A1
(43) Pub. Date: Jan. 31, 2019

(54) Tunneling Junction Transistor

(71) Applicants: Lhing Gem Kim Shoute, Edmonton (CA); Douglas W. Barlage, Edmonton (CA)

(72) Inventors: Lhing Gem Kim Shoute, Edmonton (CA); Douglas W. Barlage, Edmonton (CA)

(21) Appl. No.: 15/210,884

(22) Filed: Jul. 15, 2016

(51) Int. Cl. H01L 29/737; H01L 29/08; H01L 29/47; H01L 29/49; H01L 29/417; H01L 29/66; H01L 29/73

(52) U.S. Cl. CPC H01L 29/737; H01L 29/0895; H01L 29/47; H01L 29/7311; H01L 29/41708; H01L 29/66242; H01L 29/7317; H01L 29/4908

(57) ABSTRACT

A first of its kind polycrystalline or amorphous-based tunneling thin-film junction transistor (TJT) utilizing bipolar charge transport with a very high current density is introduced. Using the TJT architecture, this thin-film transistor (TFT) performs robustly at collector voltages at fields greater than 0.5 MV/cm with the current density output greater than 1 mA/mm without any observed electrical breakdown. Combining the principles of the tunneling emitter and the base inversion channel, the high-k dielectric/wideband gap amourphous or polycrystalline substrate/with p-type semiconductor substrate behaved most analogously to a bipolar transistor.

### FIELD OF THE INVENTION

The present invention relates to the field of semiconductors thin film technology, and more particularly to a heterojunction tunneling emitter bipolar transistor and its mode operation.

### BACKGROUND OF INVENTION

Thin film technology since its implementation continues to expand its application in the semiconductor industry. Beginning first as a niche application in display technology, where it continues to play a significant role, to thin-film solar cells, and now to the emerging field of printable and flexible electronics. The “metal oxide semiconductor field-effect transistor” (MOSFET) architecture has become the uncontested approach to realizing thin films as a transistor. Examples for different permutations of the field-effect transistor (FET) architectures are shown in FIG. 1, FIG. 2 and FIG. 3.

In general, a typical thin film transistor (TFT) is a three terminal device: the control terminal known as the “gate,” and the other two is the “drain” and “source” terminal, which are the input and output ports for the current controlled by the gate. The TFT is a unipolar device and its behaviour is dictated by the majority carrier of the active material, which is usually a semiconductor. To further elaborate, the majority carriers accumulate at the gate insulator-semiconductor interface to form a channel. When the channel is sufficiently conductive from the source terminal to the drain terminal, the device is said to be “on.” These terminals usually play a passive role in the operations of the TFT, but some architectures enable a more active role. In these instances, the source or drain contact may form a junction that can improve some device performance metrics, for example, “off” state leakage and saturation behaviour. While the semiconductor can be either inorganic or organic in nature, the current TFT material system seen in this technological landscape remain mostly a homogenous structure. This means, more specifically, that no junctions are created between two or more materials other than that which is formed by the contact between semiconductor and metal.

Active metal-semiconductor (MS) junctions are realized in an asymmetrical TFT architecture as shown in FIG. 3. In contrast to previous designs, at least one of the metals play a crucial role in achieving proper transistor operations. The metal for the source 306 in particular is chosen such that its properties lends itself to the formation of a “Schottky barrier” (SB) with the semiconductor. SB junctions play a dual role in this type of TFT: in the “off” state, it will neutralize the semiconductors carriers (either electrons with a negative charge or holes with a positive charge) up to some distance within the active film known. This is referred to as the “depletion width.” While in the “on” state, the metal becomes the source of electrons. In contrast, a passive MS junction is considered to be an “ohmic contact”, and it serves no other purpose than the allowance of current flow in and out of the active material with the source and drain as in FIG. 1 and FIG. 2.

As an example, in an n-type (electron dominated material) FET, a sufficient depletion width ensures that conduction between source 306 and drain 305 at applied gate voltages of 0 V and below are minimal. For p-type FET, this is desirable for gate voltages for 0V and above. During the “on” state in an n-type FET, a positively applied gate voltage forward-biases the SB barrier as the junction's depletion width is reduced. In this mode of operation, the source metal 306 behaves as an electron source; in other words, electrons are injected from the metal into the semiconductor which results in the rise of current conduction.

Junctions resulting from contact between two active materials with different band gaps E_{G}, have also been considered for TFTs in some instances, an example is shown in FIG. 4. These hetero-structures although not widely studied are also being considered in order to enable materials not typically used for thin film technology. However, they remain, in principle, true to the FET structure and operation; in these class of devices, instead of forming a conducting channel adjacent to the gate insulator on the semiconductor side, the channel is formed at the heterojunction between the two active material layers where, ideally, a two-dimensional gas (2DEG) is induced.

Despite this, no architectural design to date has solved the issue of low current densities usually exhibited in TFTs, including those which have been previously discussed. Sufficient current densities are crucial if it is required that the transistor be able to drive loads, or behave effectively as a non-lossy switch at frequencies demanded by a given system. High current densities are important in enabling a transistor to a wide range of applications, including power electronics and systems. As it stands, the traditional FET and its variants remain insufficient in reaching these device specifications.

### SUMMARY OF INVENTION

The proposed architecture for a TFT can be considered a novel and unexplored variant of the bipolar transistor (BJT). The terminology therefore generally follows the nomenclature convention of the BJT, with few modifications accounted by the significant differences which, in concert, results in a completely novel device architecture and operation.

In a first embodiment detailed within the article, a TFT comprises firstly of one active layer considered to be a “wide-bandgap” semiconductor. The second active layer is one without any restriction in its energy bandgap, but must be of opposite polarity in its dominant carrier type, i.e. the hole source. This is necessary in order to form a “pn-junction” at the areas which these two layers overlap. All the remaining components include an insulating barrier layer, wherein the energy bandgap must be both greater than the bandgaps of both active layers at least individually and must have a negligible free carrier concentration, on top of which sits the emitter electrode, a collector electrode electrically coupled to the wide-bandgap semiconductor, and a base control electrode electrically coupled to the hole source active film.

The second embodiment disclosed herein is a method of fabricating a TFT beginning with a substrate above which the hole source is formed, which is the active film of opposite dominant carrier polarity to the second wide-bandgap active film formed, the insulating barrier which is formed wherein the energy bandgap must be both greater than the bandgaps of at least one of the active layers and must have a negligible carrier concentration, above which the emitter electrode is formed, the base control electrode electrically coupled to the hole source which is formed, and the collector electrode layer electrically coupled to the wide-bandgap which is formed.

Further details of the architecture summarized above, its features and the advantages will be elaborated in the following detailed description and their associated figures. Each relevant structure in the figure describing the invention herein are numerical assigned, with like features assigned to like numerals for architectures with slight variation, and like numerals in the detailed description assigned to like numerals of the figures.

### BRIEF DESCRIPTION OF THE DRAWINGS

FIG. 1 shows an example of a common FET architecture known as the “bottom-gate” TFT;

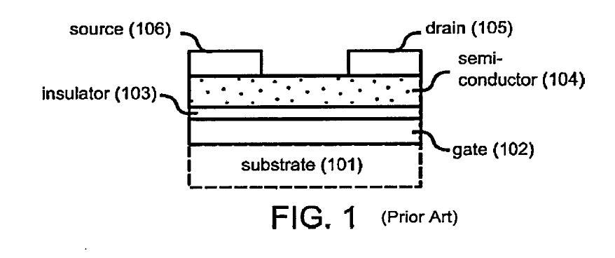

FIG. 2 shows an example of another common FET architecture known as the “top-gate” TFT;

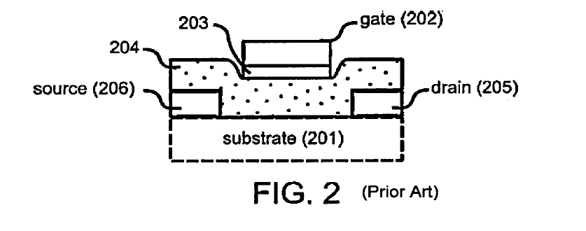

FIG. 3 shows an example of an emerging FET architecture known as the “source-gated” TFT or transistor or “Schottky-barrier” TFT or transistor;

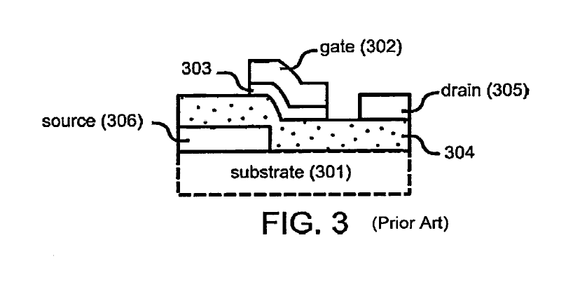

FIG. 4 shows an example of an emerging FET architecture which includes at least heterojunction between two active materials;

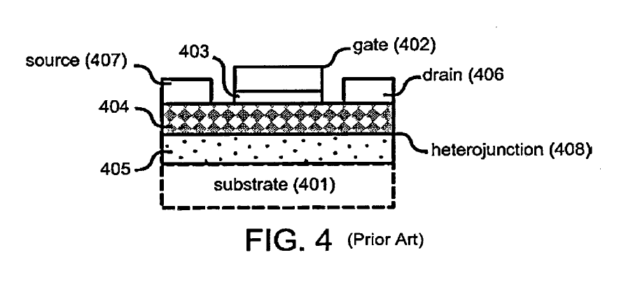

FIG. 5 shows a 3-dimensional perspective view of a device architecture for a TFT in accordance with the present disclosure;

FIG. 6 shows a 2-dimensional cross-sectional view of one of the many alternate embodiments of a device architecture where the barrier layer is extended to the collector for a TFT in accordance with the present disclosure;

FIG. 7 shows a present embodiment of the device presently disclosed for which empirical measurements were made;

FIG. 8 shows the common base mode family of curves measurement as a Collector current on a linear scale versus Collector voltage for a given V_{Base} characteristics for one of the embodiments of the TFT which was fabricated in accordance with the present disclosure;

FIG. 9 shows the capacitance and conductance measurement versus Emitter-Base voltage or “Voltage (V_{A})” for one of the embodiments of the TFT which was fabricated in accordance with the present disclosure;

FIG. 10 is a flow diagram of the one general methodology of fabricating a TFT in accordance with the present disclosure.

### DETAILED DESCRIPTION OF THE INVENTION

In the following description, the energy bandgap of a semiconductor is considered “wide” if it is greater than 1 eV.

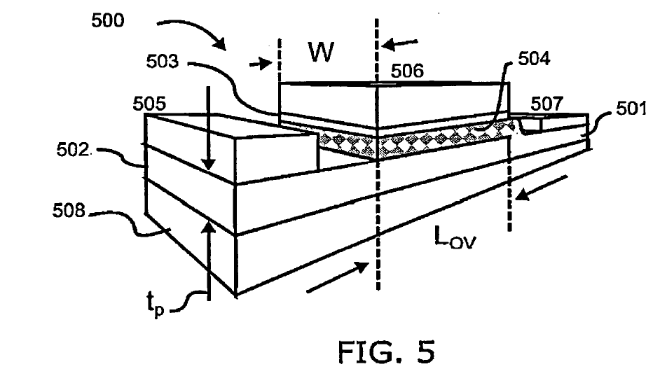

FIG. 5 shows a view of a device structure for a TFT 500 in accordance to the present disclosure. The hole source 502 is formed on a substrate 508 and patterned in such a way that will be clear further on. After the formation and patterning of the hole source 502, a thin wide-bandgap (WB) semiconductor film 501 forms on top of both the substrate and the patterned hole source, and also patterned accordingly. An insulating layer 503, which also can be called the barrier layer, is formed upon the WB layer 501. The architecture is then completed when the electrodes are fashioned at their respective terminals: at the base control electrode 505, which may be directly formed above the hole source 502, the emitter electrode 506 which may be directly formed above the barrier layer 503, and the collector electrode 507 which may be directly formed above the WB layer 501.

The pn-junction area between the hole source 502 and the WB layer 501 are indicated. Both the hole source 502 and the WB active film 501 are patterned such that the full extent of the hole source 502 is not in contact with the WB film 501. Instead, only a portion of the length of both the hole source 502 and WB film 501 comes into contact with each other to form a pn-junction; the overlap length L_{OV} is also shown in 500. In FIG. 5, it is also shown that the width of the pn-junction generally extends to the width of both the hole source 502 and the WB layer 501, and it is labeled “W.” Like overlap length L_{OV}, the overlap width W can also be modified. The overlap length L_{OV} and width W between the hole source 502 and WB film 501 in 500 can be varied to slightly modify the output characteristics of the device, but it still operates under the same principles.

The overlapping area determined by W and L_{OV} effects the output characteristics of the device by modifying formation of the “referred base” situated between the barrier layer 503 and the hole source layer 502. An example of the distribution of the referred base is labeled 504 in FIG. 5.

The barrier layer 503, also known as the insulating layer, may be any material with an energy bandgap that is larger than at least the one of the semiconductor layer 501 or 502, but it is more preferred that it be larger than at least the WB layer 501, and most preferred if the energy bandgap of the barrier layer 503 is larger than both the WB layer 501 and the hole source 502. If the aforementioned trend described above is followed, in general, the transconductance of the device will also increase. Beyond energy bandgaps of 10 eV for the bather layer 503 material, the device will cease to function as an effective BJT. The height of the energy barrier between the WB layer 501 and the barrier layer 503 determines the amount of electrons that is able to tunnel across the energy barrier. The larger the energy barrier, in terms of eV, the likeliness of electron tunneling decreases across the energy barrier; the smaller the energy barrier, the likeliness of electron tunneling increases across the energy barrier.

A second stipulation for the barrier layer 503 is that the material must be an insulating material. In other words, it must have a negligible free carrier density or a low number of density of states such that electrons from both the emitter electrode 506 or the holes originating from either the hole source 502 or the WB layer 501 cannot easily conduct across the material in the absence of external stresses or conditions, including high applied fields or energy band tailoring and so forth.

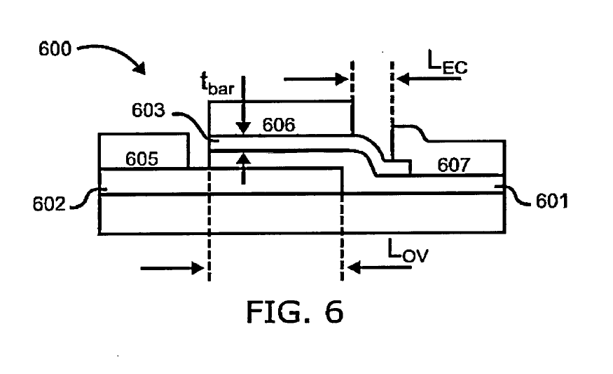

Another critical parameter for the barrier layer 503 is its thickness. This is also denoted as “t_{bar}” in 600 in FIG. 6. Should t_{bar} be too thick, the device will cease to behave as an effective BJT; should t_{bar} be less than a monolayer thick or eliminated entirely, the device will cease to behave as an effective BJT. As such, a range of thickness for t_{bar} is suggested to be anywhere between approximately 20 nanometers (nm) to at least one atomic layer of the selected barrier layer material.

The overlap between WB layer 501 and hole source layer 502, L_{OV}, up to this point, is taken to assume a positive value. However, in some embodiments, L_{OV} can also be chosen to have a negative value. By this it is meant that both a positive Euclidean distance (L_{OV}>0 cm) and a negative Euclidean distance (L_{OV}<0 cm) can be chosen for L_{OV}.

If L_{OV}>0 cm, then the total pn-junction surface area is the area of both of the product of L_{OV} and width W of 502, the hole source layer, and the thickness of 501, the hole source layer tₚ and W. Such an embodiment is considered within the scope of this disclosure.

If L_{OV}<0 cm, then the total pn-junction surface area is the area of the hole source layer 502 width W and also its thickness tₚ. The latter, tₚ×W is the area of the hole source 502 which is exposed to the WB layer 501. Such an embodiment is considered within the scope of this disclosure.

The base control electrode 505 is in electrical contact with the hole source 502. The type of contact is an ohmic contact or a Schottky contact with minimal resistance. The base control electrode can be any metal or appreciably conductive material or material alloy that achieves either the ohmic or Schottky contact. If transparency is required, extremely thin metal (˜8 nm) nanostructures, or indium tin oxide (ITO), among many other transparent electrodes available, can be also be used to form the base control electrode 505.

For some embodiments of the device disclosed herein, the hole source 502 and the base control electrode 505 may in fact be the same material. Such is the case if the material is sufficiently conductive due to a high free hole carrier concentration.

The collector electrode 507 is in electrical contact with the WB layer 501. The type of contact is an ohmic contact or a Schottky contact with minimal resistance. The collector electrode can be any metal or appreciably conductive material or material alloy that achieves either the ohmic or Schottky contact. If transparency is required, extremely thin metal (˜8 nm) nanostructures, or indium tin oxide (ITO), among many other transparent electrodes available, can be also be used to form the collector electrode 507. For one example, if gallium nitride is chosen as the WB layer, then a viable electrode be formed on top of the WB layer would be a material alloy consisting of titanium, aluminum, nitride and gold (Ti/Al/Ni/Au).

The emitter electrode 506 is in contact with the barrier layer 503. Any material that exhibits fairly high conductivity material such as a metal (for example, ITO, aluminum Al, gold Au, etc.), or material alloy such as a metal alloy (for example, boron nitride, nickel/gold Ni/Au stack, etc.) can be used as the emitter electrode 506. A good contact is required such that there is minimal voltage drop at the emitter electrode 506 and the barrier layer 503 interface. As a rule, depending on the emitter dielectric used for the barrier layer 503, the designer may select the electrode constituting the emitter 506 that results in the best interface between these two layers accordingly. As an example, if silicon dioxide SiO₂ is chosen as the barrier dielectric, then an excellent electrode to be formed on top the dielectric would be highly doped polysilicon. Metals such as titanium, aluminum, titanium nitride, tantalum nitride are deposited on the high-k gate dielectric, but are not limited to them.

The device disclosed can also be scaled for its breakdown field characteristics by modifying the distance between the collector-facing edge of the emitter electrode 506 to the front edge of the collector electrode 507. An illustration of this dimension is given FIG. 6, and is labeled as L_{EC}.

A similar embodiment of the device disclosed here in is shown in FIG. 6 600. Compared to the barrier layer 503 of FIG. 5 500, the span of the barrier layer in 603 of FIG. 6 600 extends up to the collector electrode 607 and even slightly underneath, as a single example. Hence, the span of the barrier layer 603 of any embodiment of this device can span up to and beyond the edge of the collector electrode 607. The only stipulation that must hold is that the emitter electrode 606 should have minimal or no contact with the WB layer 601 lying directly underneath the barrier layer 603, and to this end, the barrier layer 603 must span to at least control base-facing edge of the emitter electrode 506.

In an alternative embodiment of the device disclosed herein, the hole source 502 and the substrate 508 may in fact be the same material.

Thin film transistor architecture that adopts an architecture in accordance with the present disclosure has the property of producing high current densities and is able to withstand relatively high applied electric fields. Furthermore, such a TFT behaves similarly to a bipolar transistor (BJT), which is more apparent in its corresponding current-voltage (IV) measurements.

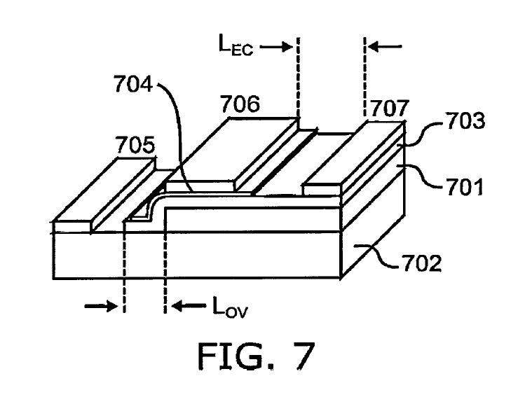

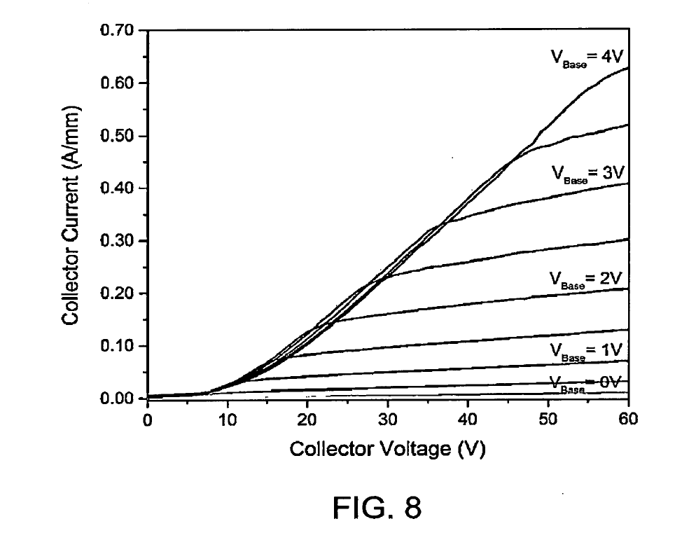

An example of an expected IV measurement of a built device architecture that follows the design procedure described within the article is shown in FIG. 8. This measurement is for a device shown in FIG. 7 which is but one instance of an embodiment of the disclosed thin film transistor architecture. Assuming that the WB layer 701 is fully depleted of its free-carriers and with the potential drop across the hole source layer 702 being minimal, the electric-field is able to withstand is at least according 0.5 MV/cm. Functionality at high electric-fields enables this device and its like embodiments to perform in a range of low to high power applications. In addition, this instance of the architecture is able to perform consistently up to at least 20 V with a single metal layer at the collector electrode 507. If higher collector voltages are demanded from the device, using more robust electrodes materials, as previously suggested within the disclosure, is recommended.

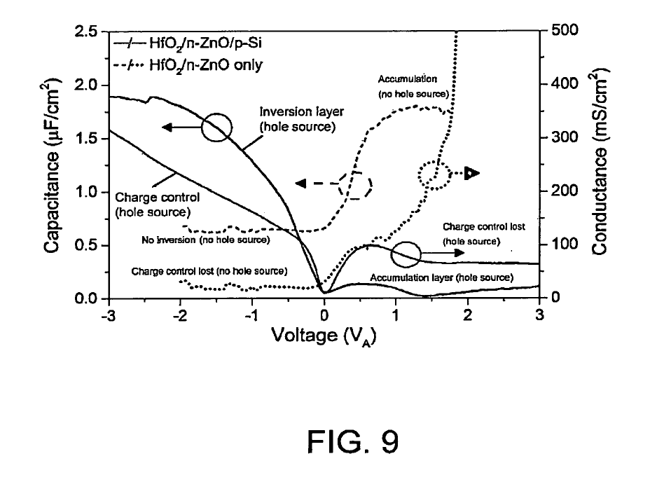

As shown in FIG. 9, within a gate bias range of −3 V to +3 V, this instance of the thin film bipolar transistor is able to reach a capacitance density of just over 1.8 μF/cm² at inversion voltage range which is in this embodiment is when the voltage is below 0 V This value is much higher than the capacitance density observed at voltages greater than 0 V, which in this case is the accumulation voltage range. Also at the inversion voltage range, the conductance density is measured to be higher than 300 ms/cm², which greater than what is measured at accumulation voltage range (greater than 0 V). This is a characteristic of all embodiments of this the device currently disclosed.

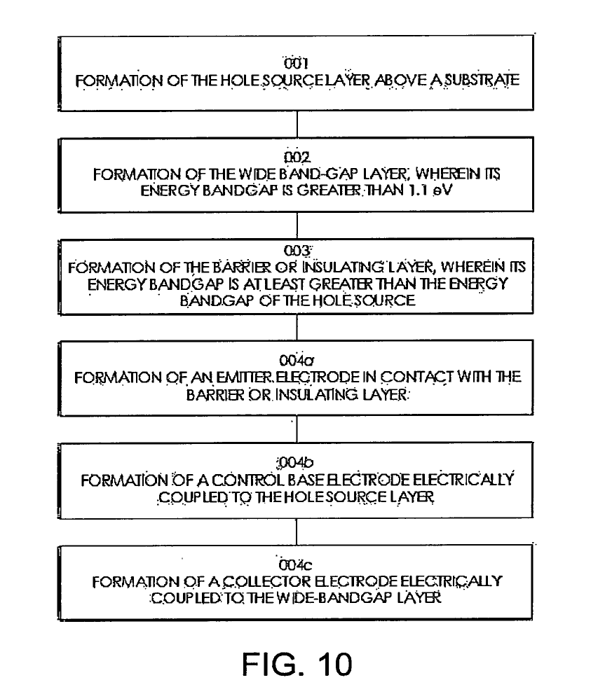

FIG. 10 is a flow diagram for fabricating a TFT in accordance with the present disclosure.

In reference to FIG. 10, the process begins first with the formation of the hole source layer as step 001, which must be able to supply free p-type carriers. The following step 002 is the formation of the WB layer, which must have an energy bandgap that is greater than 1 eV and must be also be able to supply free n-type carriers. Then in step 003, the barrier layer or insulating layer is formed and must have an energy bandgap at least greater than the hole source layer previously mentioned. In the next step 004a an emitter electrode is formed on the barrier layer. Then in the following step 004b a controlled base electrode is formed and is electrically coupled to the hole source layer. Next is step 004c a collector electrode is formed and is electrically coupled to the WB layer. It is allowable that 004a, 004b, and 004c are the same material, if it is satisfactory.

Thus the architecture of a thin-film bipolar transistor has been described. With the invention now described in accordance with the requirements of patent statutes, those whom are proficient in the field may easily ascertain the necessary modifications and changes to the present invention to meet their required specifications or conditions. The applicants have considered both the described and modified embodiments which may be considered in alternative or future adaptions; it is not intended to be limiting to the precise forms described within the statute, nor is it an exhaustive account for both the structural design and the process in which the invention can be realized practically. As such, the scope of this invention is not bounded by the specifics exercised throughout the development and disclosure thereof, but rather the declared claims of the article.

What is claimed is:

1. A bipolar thin-film transistor (TFT) comprising:
a hole source layer, wherein its majority carrier type is p-type or holes or polaron or quantum mechanical particles with positive charge, which are of opposite charge of an electron and whose energy bandgap is not limited to any value;
a wide-bandgap (WB) layer, wherein its energy bandgap is at least greater than 1 electron volt (eV);
a barrier layer or insulator layer, wherein its energy bandgap is at least greater than the material used as the hole source layer and has sufficiently low density of states;
a control base electrode electrically coupled to the hole source layer;
an emitter electrode in contact with the barrier layer; and,
a collector electrode electrically coupled to the WB layer.

2. The TFT of claim 1 wherein:
the hole source layer and the WB layer have an overlap sufficient to form a p-n junction; or,
the source layer and the WB layer have a contact sufficient to form a p-n junction.

3. The TFT of claim 1 wherein:
the barrier or insulator layer is between one atomic layer of the insulator's atomic or molecular composition up to approximately 20 nanometers thick; and,
the bandgap of the barrier or insulator layer no less than the bandgap of the hole source layer and no greater than 10 eV; and,
the energy barrier difference of the barrier layer and higher conduction energy band edge among the WB layer or the hole layer is such that electron tunneling probability is boosted; and,
a “referred base” is formed between the barrier layer and the hole source layer.

4. The TFT of claim 1 wherein the hole layer can be either:
a semiconductor;
a polymer; or,
a conductor.

5. The TFT of claim 1 wherein the control base electrode can be either:
a metal;
an alloy;
a semiconductor;
a polymer, or;
any combination thereof.

6. The TFT of claim 1 wherein the emitter electrode can be either:
a metal;
an alloy;
a semiconductor;
a polymer, or;
any combination thereof

7. The TFT of claim 1 wherein the collector electrode can be either:
a metal;
an alloy;
a semiconductor;
a polymer, or;
any combination thereof

8. The TFT of claim 1 wherein a maximum collector current density is greater than 2 mA/mm.

9. The TFT of claim 1 wherein the forward breakdown voltage is greater than 20 V at the collector electrode.

10. The TFT of claim 1 wherein the transverse breakdown field at the emitter electrode is greater than 0.1 MV/cm.

11. The characteristic of the TFT of claim 3 wherein:
the electron tunneling probability is greater than 0;
the electron tunneling probability is higher than that which would be the case should only either the WB layer or hole source layer is used as the active layer, and as a result, no heterojunction is formed.

12. The referred base of the TFT of claim 3 wherein:
a quantum inversion well or layer is formed; and,
the inversion layer comprises of carriers of opposite charge polarity to the majority intrinsic carrier type of the WB layer.

13. The inversion layer base enables the use of a higher doping concentration collector
ultra thin, extremely high carrier concentration base allows more charge to be present in the collector while maintaining higher gain
the higher doped collector ensures a unidirectional operation of the transistor (at forward bias conditions)

14. The use of high tunneling emitter electrode allows work function design of the device turn-on voltage
various electrode metals, Titanium, aluminum, gold, nickel platinum and various other metals with varying work functions can be used to adjust the turn on voltage
such that, different base doping can alter the turn on voltage with minimal effects on the tunneling current

15. A method of fabricating a thin-film transistor (TFT) comprising:
forming a hole source layer above a substrate;
forming a WB layer which spans above the hole source layer and the substrate, wherein the WB layer has an energy bandgap of greater than 1 eV;
forming a barrier or insulator layer above the WB layer, wherein its energy bandgap is at least greater than the material used as the hole source layer and has sufficiently low density of states;
forming a control base electrode electrically coupled to the hole source layer;
forming an emitter electrode in contact with the barrier layer; and,
forming a collector electrode electrically coupled to the WB layer.

16. The fabrication method can be achieved with a number of chemical vapor deposition methods, pulsed laser deposition or sputtering using various lithographic techniques.
The formation of a hole source, such as boron doped silicon, PEDOT:pss, copper oxide or tin oxide is deposited.
A channel material with energy gap greater than the source material, such as ZnO are deposited on top of the electrode.
A tunneling barrier with energy gap greater then the channel material the blocks holes from the substrate.
An emitter electrode with work function chosen to allow emission of electrons into across the barrier into the electrode.
A control electrode on the hole source material which modulates the number of holes in the referred base.
An electrode formed on the channel material to serve as the base electrode.

17. For proof of concept and other details related to the described device please refer to the attached Schedule A.
